(19) United States
(12) Patent Application Publication
(10) Pub. No.: US 2025/0291990 A1
(43) Pub. Date: Sep. 18, 2025

(54) METHOD FOR LEARNING-BASED AUTO PLACEMENT OF ANALOG CIRCUIT

(71) Applicant: Novatek Microelectronics Corp., Hsinchu (TW)

(72) Inventor: Chou Chen Lee, Taipei City (TW)

(73) Assignee: Novatek Microelectronics Corp., Hsinchu (TW)

(21) Appl. No.: 18/603,257

(22) Filed: Mar. 13, 2024

(51) Int. Cl. G06F 30/392; G06F 30/398

(52) U.S. Cl. CPC G06F 30/392; G06F 30/398

(57) ABSTRACT

A method for learning-based auto placement of analog circuit is proposed. The method includes acquiring a netlist file of an analog circuit including plural devices, obtaining a total number of plural wells of the analog circuit and the number of devices sharing a first well which has the greatest number of devices sharing the same well among the wells according to the netlist file, determining the number of plural bounded-sliceline grid (BSG) units according to the total number of the wells, determining a size of each BSG unit according to the number of devices sharing the first well, and performing a training process by using a reinforcement learning model comprising an actor model and a critic model, to determine an optimum placement plan.

### TECHNICAL FIELD

The disclosure relates to a technique for learning-based auto placement of analog circuit.

### BACKGROUND

Analog placement is a prominent topic in analog layout synthesis for achieving ultimate analog layout quality and circuit performance. It determines physical locations of analog building blocks in an analog integrated circuit (IC) composed of either one or multiple devices before they are interconnected. To efficiently measure analog layout quality in the physical domain, which correlates to circuit performance in the electronical domain, during analog placement, it is essential to minimize total chip area and estimated interconnecting wire-length while considering the most critical analog placement constraints.

### SUMMARY OF THE DISCLOSURE

Accordingly, a method for learning-based auto placement of analog circuit is proposed.

According to one of the exemplary embodiments, the method includes acquiring a netlist file of an analog circuit including plural devices, obtaining a total number of plural wells of the analog circuit and the number of devices sharing a first well which has the greatest number of devices sharing the same well among the wells according to the netlist file, determining the number of plural bounded-sliceline grid (BSG) units according to the total number of the wells, determining a size of each BSG unit according to the number of devices sharing the first well, and performing a training process by using a reinforcement learning model including an actor model and a critic model to determine an optimum placement plan. The netlist file defines basic information describing each device and includes connecting net names and size of the device, and where the reinforcement learning model includes an actor model and a critic model. The training process includes to place a first device block of the devices in a first grid structure consisting of the plurality of BSG units merged in a first arrangement, by using the reinforcement learning model, to form a first placement plan and to placing the devices of the analog circuit in another grid structure consisting of the plurality of BSG units merged in an arrangement different from the first arrangement, where each device block of the devices is a device or a combination of at least two devices.

It should be understood, however, that this summary may not contain all of the aspect and embodiments of the disclosure and is therefore not meant to be limiting or restrictive in any manner. Also, the disclosure would include improvements and modifications which are obvious to one skilled in the art.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 illustrates a schematic diagram of an electronic apparatus in accordance with an exemplary embodiment of the disclosure.

FIG. 2 illustrates a flowchart of a method for learning-based auto placement of analog circuit in accordance with an exemplary embodiment of the disclosure

FIG. 3 illustrates a schematic diagram and implementations of a method for learning-based auto placement of analog circuit in accordance with one of the exemplary embodiments of the disclosure.

FIG. 4A illustrates a schematic diagram of a placement subject to the proximity constraint in accordance with an exemplary embodiment of the disclosure.

FIG. 4B illustrates a schematic diagram of a placement subject to the symmetry-island constraint in accordance with an exemplary embodiment of the disclosure.

FIG. 5 illustrate a flowchart of a training process for auto placement of analog circuit in accordance with an exemplary embodiment of the disclosure.

FIG. 6A-6C illustrate schematic diagrams of a symmetry-island refinement algorithm in accordance with an exemplary embodiment of the disclosure.

To make the above features and advantages of the application more comprehensible, several embodiments accompanied with drawings are described in detail as follows.

### DESCRIPTION OF THE EMBODIMENTS

Some embodiments of the disclosure will now be described more fully hereinafter with reference to the accompanying drawings, in which some, but not all embodiments of the application are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

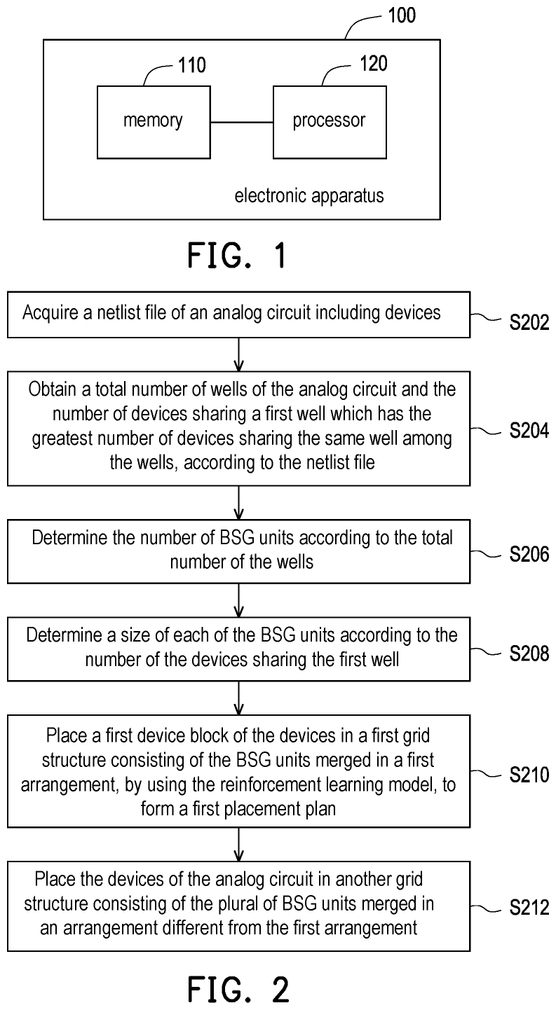

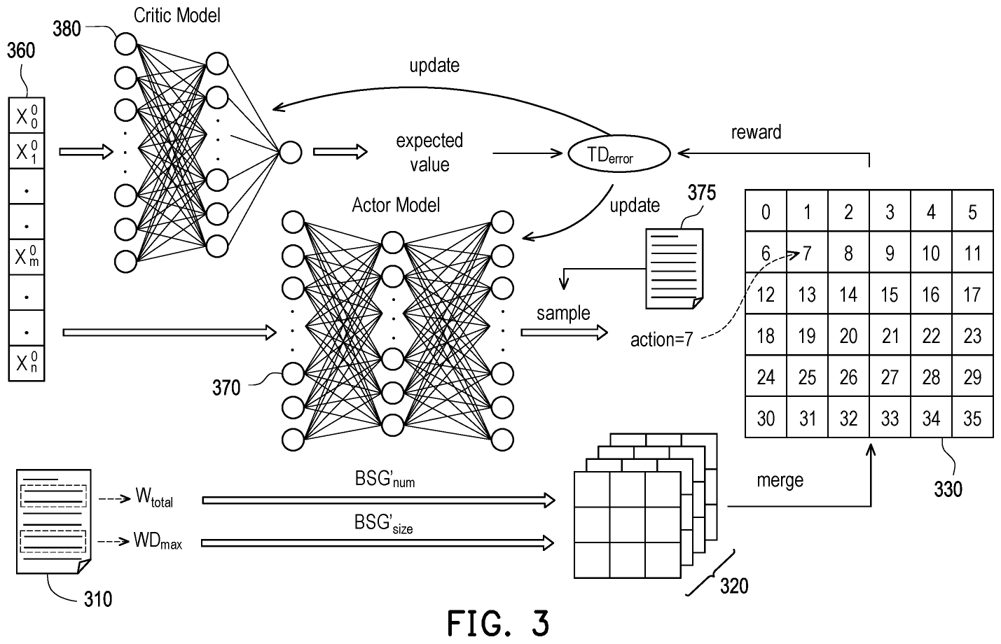

FIG. 1 illustrates a schematic diagram of an electronic apparatus in accordance with an exemplary embodiment of the disclosure. All components and configurations of the electronic apparatus are first introduced in FIG. 1. The functionalities of the components are disclosed in more detail in conjunction with FIG. 2.

Referring to FIG. 1, an electronic apparatus 100 would at least include a memory 110 and a processor 120. The electronic apparatus 100 may be an electronic system or a computer system. The memory 110 may be many forms of non-volatile storage device, such as flash memory, non-volatile random access memory (NVRAM), hard disk drive (HDD) and solid-state drive (SSD). The processor 120 may be one or more of a North Bridge, a South Bridge, a field programmable array (FPGA), a programmable logic device (PLD), an application specific integrated circuit (ASIC), other similar devices, or a combination thereof. The processor 120 may also be a central processing unit (CPU), a programmable general purpose or special purpose microprocessor, a digital signal processor (DSP), a graphics processing unit (GPU), other similar devices, or a combination thereof.

FIG. 2 illustrates a flowchart of a method for learning-based auto placement of analog circuit in accordance with an exemplary embodiment of the disclosure, where the steps of FIG. 2 could be implemented by the electronic apparatus 100 as illustrated in FIG. 1.

Referring to FIG. 2 in conjunction with FIG. 1, the processor 120 would acquire a netlist file of an analog circuit including devices (Step S202). Herein, the netlist file would define basic information describing each device. Such basic information may include (1) net names of nets that a device is connected to and are represented by numerical numbers, alphabetical letters, and alphanumeric characters, (2) a name of a power net that a well, such as n-well or p-well, in which a device is located at is connected to, (3) the size of a device (e.g. length and width), and so forth.

Next, the processor 120 would obtain a total number of wells of the analog circuit and the number of devices sharing a first well which has the greatest number of devices sharing the same well among the wells, according to the netlist file (Step S204).

In detail, the processor 120 would determine the number of bounded-sliceline grid (BSG) units according to the total number of the wells (Step S206) and determine a size of each of the BSG units according to the number of the devices sharing the first well (Step S208). Herein, the number of the BSG units may not be less than the total number of the wells. In one exemplary embodiment, a length (represented by the number of BSG units in a horizontal direction) and a width (represented by the number of BSG units in a vertical direction) of each BSG unit may be determined based on a square root of the maximum number of devices plus a constant to avoid wasting too much unnecessary memory space, and yet the disclosure is not limited in this regard. Different grid structures may be formed by merging the BSG units in different arrangements (regarding to relative positions of the BSG units). Thus, a training process for determining an optimum placement plan may be running based on the grid structures, by using a reinforcement learning model comprising an actor model and a critic model. The training process includes placing each device block of the plurality of devices of the analog circuit in one grid structure of a plurality of grid structures, changing the used grid structure to an un-used grid structure after the plurality of devices are completely placed in the used grid structure, and repeating performing the step of placing each device block of the plurality of devices in a different grid structure whose BSG units are merged in a different arrangement.

For a simple and clear introduction, following steps S210 and S212 are described as steps in the training process. The processor 120 may place a first device block of the plurality of devices in a first grid structure consisting of the plurality of BSG units merged in a first arrangement, by using the reinforcement learning model, to form a first placement plan (Step S210), and the processor 120 may place the plurality of devices of the analog circuit in another grid structure consisting of the plurality of BSG units merged in an arrangement different from the first arrangement (Step S212). In detail, the actor-critic model is a type of reinforcement learning model that combines aspects of both policy-based algorithm and value-based algorithm. Under such hybrid framework, the processor 120 may use the actor model to learn a policy to make decisions and use the critic model to evaluate the actions taken by the actor model to efficiently search for analog circuit placement for the devices.

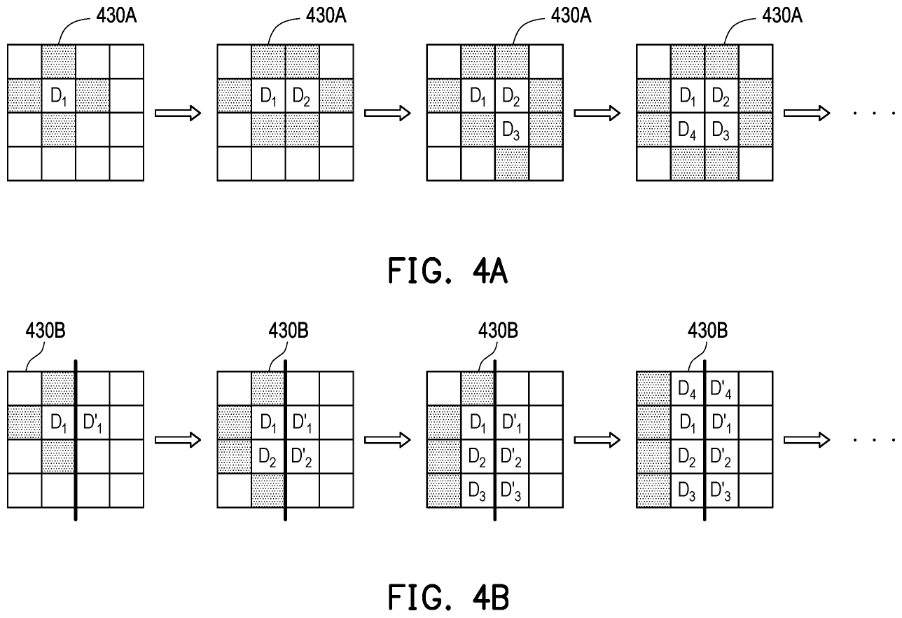

For better comprehension, FIG. 3 illustrates a schematic diagram and implementations of a method for learning-based auto placement of analog circuit in accordance with one of the exemplary embodiments of the disclosure, and the method of FIG. 3 could also be implemented by the electronic apparatus 100 as illustrated in FIG. 1.

Referring to FIG. 3 in conjunction to FIG. 1, similar to Steps S202-Step S210 in FIG. 2, the processor 120 would acquire a netlist file 310 of an analog circuit including devices to accordingly obtain a total number of wells of the analog circuit Wₜₒₜₐₗ and the number of devices sharing a first well WDₘₐₓ. The processor would determine the number of BSG units BSG′ₙᵤₘ according to the total number of the wells Wₜₒₜₐₗ and determine a size of each of the BSG units BSG′ size according to the number of the devices sharing the first well WDₘₐₓ, and further create a grid structure 330 by merging the BSG units 320.

Next, the processors 120 would generate node embedding information corresponding to device blocks according to the netlist file 310, where each device block is a device or a combination of at least two devices of the analog circuit. The processors 120 would generate the plurality of node embedding information by using an inductive representation learning model, such as a Graph SAmple and aggreGatE (GraphSAGE) model. The processor 120 would input the node embedding information respectively into an actor model 370 and a critic model 380. The actor model 370 in combination of the critic model 380 may be a type of a reinforcement learning model, having two hidden layers. Assume that the node embedding dimension of each device is set to 128. The hidden layers of the actor model 370 and the critic model 380 may be of size (128, 128) and (128, 64) respectively.

The processor 120 would generate multiple actions as outputs of the actor model 370 in response to first node embedding information 360 of the node embedding information, where the first node embedding information 360 is corresponding to a first device block of the device blocks of the analog circuit and is as an input to the actor model 370. The processor 120 selects a first action from the generated actions according to a placement constraint 375 adapted for placing the first device block in the grid structure, wherein the first action indicates a grid position of the grid structure 320 (e.g. the first action is 7 in this case). Next, the processor 120 may generate a reward corresponding to the first placement plan formed in response to placing the first device block according to the first action, where the reward is a function of an entire placement area of the analog circuit and a half-perimeter wirelength (HPWL) of the entire placement area of the analog circuit. Every time a device is placed, the reward will be updated.

In one exemplary embodiment, the reward rₜ with respect to the current state may be represented as follows:

$${r}_{t} = x * \frac{{\sum }_{D} {D}_{a}}{{P}_{w} * {P}_{l}} + y * \frac{{\sum }_{N} 1 - ( \frac{{N}_{HPWL}}{{P}_{w} + {P}_{l}} )}{{N}_{n}} ,$$

where Dₐ denotes area, N_{HPWL} denotes HPWL, P_{w} denotes placement width, Pₗ denotes placement length, Nₙ denotes number of nets, and (x, y) is the grid position indicated by the first action in a coordinate system.

On the other hand, the processor 120 would generate a first expected value as an output of the critic model 380, where the first expected value is with respect to a current state which represents a current placement plan before the first device block is being placed in the first grid structure according to the first action. It is noted that in the training process using the actor model 370 and a critic model 380, the term “state” is used to represent a placement environment which is also regarded as a placement plan. An initial state so, as the beginning of placing the devices, is the random assignment of the devices in a preconfigured grid structure. Moreover, the processor 120 would generate a second expected value as another output of the critic model 380, where the second expected value is with respect to a new state next to the current state, and the new state represents the first placement plan formed in response to that the first device block has been placed in the first grid structure according to the first action. The processor 120 would compute a temporal difference error TDₑᵣᵣₒᵣ according to the reward, the first expected value, and the second expected value.

Next, the processor 120 would update parameters of the actor model 370 according to the temporal difference error TDₑᵣᵣₒᵣ by leveraging Proximal Policy Optimization algorithm. In one exemplary embodiment, the actor model 370 may calculate a loss function as follows:

$${Actor}_{loss} = {J}_{PPO}^{{θ}^{k}} ( θ ) \approx {\sum }_{( {s}_{t} , {a}_{t} )} min ( \begin{matrix}\frac{{p}_{θ} ( {a}_{t} \vert {s}_{t} )}{{p}_{{θ}^{k}} ( {a}_{t} \vert {s}_{t} )} {A}^{{θ}^{k}} ( {s}_{t} , {a}_{t} ) , \\ clip ( \frac{{p}_{θ} ( {a}_{t} \vert {s}_{t} )}{{p}_{{θ}^{k}} ( {a}_{t} \vert {s}_{t} )} , 1 - ϵ , 1 + ϵ ) {A}^{{θ}^{k}} ( {s}_{t} , {a}_{t} )\end{matrix} )$$

Herein, p_{θ}(aₜ|sₜ) denotes the probability of choosing action at with respect to the current state sₜ, and A^{θ}^{^{k}} (sₜ, aₜ) is the temporal difference error TDₑᵣᵣₒᵣ. Next, the processor 120 would change the current state sₜ to the new state sₜ₊₁. The temporal difference error TDₑᵣᵣₒᵣ may be represented as follows:

$${TD}_{error} = α * ( {r}_{t} + γ {q}_{t + 1} - {q}_{t} )$$

Herein, rₜ denotes current reward, qₜ denotes expected value with respect to current state sₜ, qₜ₊₁ denotes expected value with respect to new state sₜ₊₁. α is a convergence constant, and γ is a decay constant between 0 and 1.

Next, the processor 120 would update parameters of the critic model 380 according to the temporal difference error, the first expected value, and the second expected value. In one exemplary embodiment, the critic model 380 may calculate a loss function as follows:

$${Critic}_{loss} = {( {TD}_{error} + {q}_{θ} ( {s}_{t} , {a}_{t} ) - {q}_{{θ}^{′}} ( {s}_{t} , {a}_{t} ) )}^{2}$$

Herein, q_{θ}(aₜ, sₜ) represents the first expected value and q_{θ′}(aₜ, sₜ) represent the second expected value.

Note that the processor 120 would use the expected value qₜ and the reward rₜ to calculate the loss function of the actor model 370 and slowly update the parameters in the actor model 370 and the critic model 380 stepwisely to minimize the temporal difference error TDₑᵣᵣₒᵣ.

The processor 120 would process the other node embedding information in a similar fashion to the first node embedding information. Herein, the processor 120 would input node embedding information to the actor model 370 and the critic model 380 sequentially according to a placement priority which is determined according to the importance of device blocks of the analog circuit. For example, the placement priority from highest to lowest may be: a differential pair, an operational amplifier current mirror, a bias current mirror, a capacitor, and other devices. Moreover, a device or a device block with the largest area among devices or device blocks having the same the placement priority are placed first.

In addition, the aforesaid placement constraint 375 may be a well-island constraint, a proximity constraint, and a symmetry-island constraint.

The well-island constraint allows allocating the same MOS type of devices to the same BSG unit, and therefore each BSG unit is considered independent and is processed in turn.

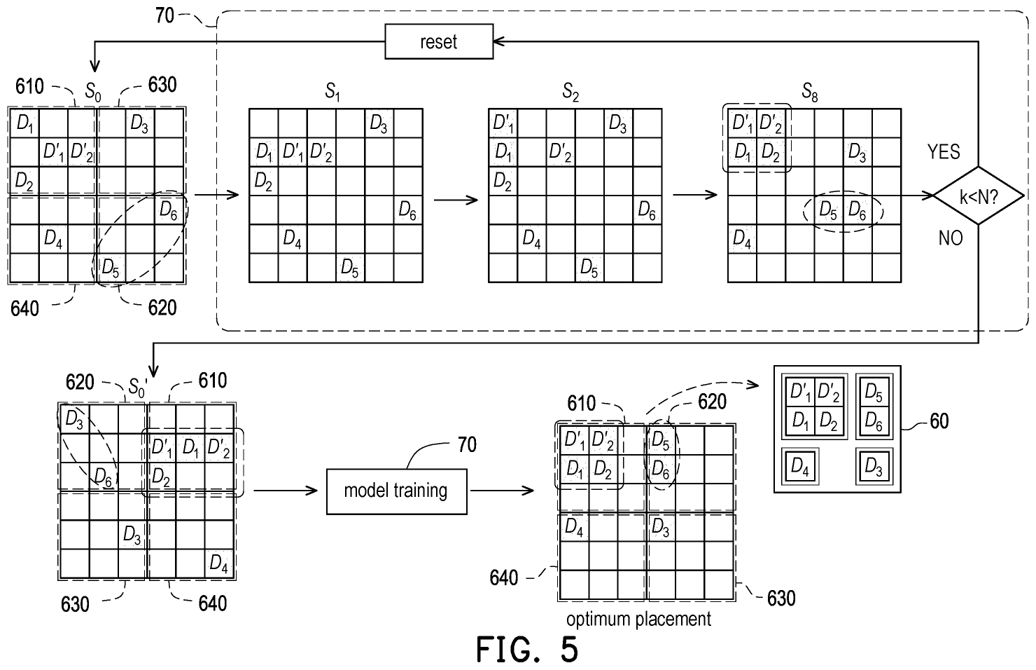

The proximity constraint allows allocating devices in a proximity device group to be placed in proximity to each other. As in FIG. 4A which illustrates a schematic diagram of a placement subject to the proximity constraint in accordance with an exemplary embodiment of the disclosure, the processor 120 may choose a device D1 from the proximity device group and placed in a grid structure 430A, use Breath-First Search algorithm to search for surrounding positions around the device D1, remove non-empty positions and decide the rest of devices D2, D3, D4 . . . need to be placed, and repeat above steps until all the devices in the proximity device group are placed.

The symmetry-island constraint allows devices in a symmetry device group to be placed proximity and symmetrically to each other. As in FIG. 4B which illustrates a schematic diagram of a placement subject to the symmetry-island constraint in accordance with an exemplary embodiment of the disclosure, the processor 120 may determine a symmetry axis AX and its direction (vertical or horizontal) cause the devices in the symmetry group have a common symmetry axis. In terms of a device pair (Dx, Dx′) for all (D1, D1′), (D2, D2′), (D3, D3′), (D4, D4′) . . . , the processor 120 would first place the device Dx in a grid structure 430B in a same fashion as the technique proposed in the proximity constraint, and the processor 120 would further place the device Dx′ at a position symmetrical to the position at which the device Dx is placed with respect to the symmetry axis.

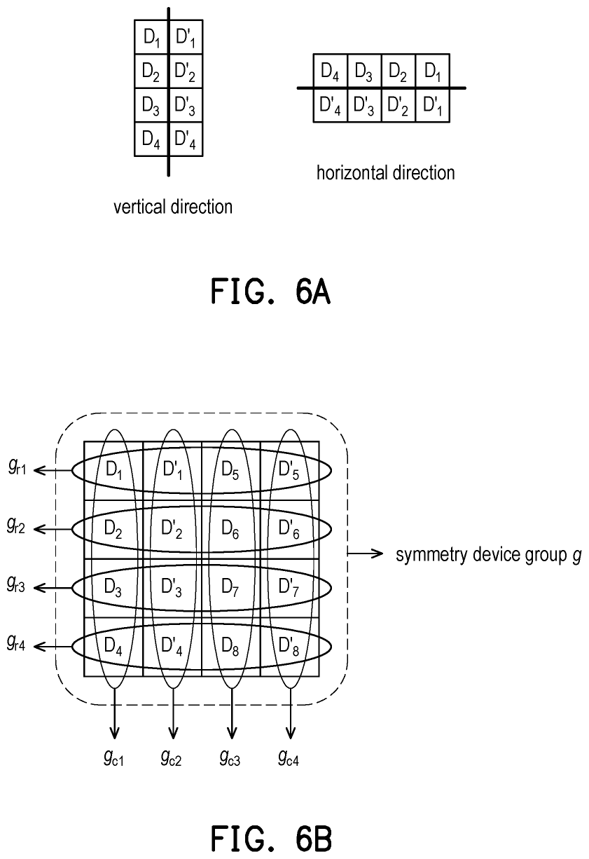

FIG. 5 illustrates a flowchart of a training process for auto placement of analog circuit in accordance with an exemplary embodiment of the disclosure, where the steps of FIG. 5 could be implemented by the electronic apparatus 100 as illustrated in FIG. 1. FIG. 5 illustrates a training process including the process of FIG. 2 and FIG. 3.

Referring to FIG. 5 in conjunction to FIG. 1, the processor 120 would randomly generate an initial state so as the beginning of placing the devices, which is the random assignment of locations of the devices in a preconfigured grid structure. FIG. 5 illustrates a same MOS type of devices (or device blocks) among the devices (or device blocks) D₁-D₆, D₁′, and D₂′ being allocated to a same BSG unit to ensure well-island generation. For example, the devices D₁ and D₁′ having a same MOS type as well as D2 and D₂′ having a same MOS type are allocated to a BSG unit 610, and the devices D₅ and D₆ having a same MOS type are allocated to a BSG unit 620.

Next, the processor would start the training process using the reinforcement learning model that includes an actor model and a critic model, by selecting a to-be-placed device according to the placement priority from the device D₁, D₁′, D2 and D₂′. For example, the processor selects the device D₁ first, and the node embedding information of the device D₁ is input to the reinforcement model to determine a selected action, which leads to a new location of the device D₁ in the placement plan of the initial state S₀. In response to that device D₁ is placed, another placement plan different from that of the initial state is formed, regard as state S₁. Next, the processor 120 selects the device D₁′ to be placed according to the placement priority, and the node embedding information of the device D₁′ is input to the reinforcement model to determine a selected action, which leads to a new location of the device D₁′ in the placement plan of the state S₁, and the states transits to state S₂. When the devices D₁, D₂, D₁′ and D₂′ are completely placed, the processor 120 places devices in another same well, until the devices D₁-D₆, D₁′ and D₂′ are completely placed. Details of the reinforcement learning model and the placement priority have been provided in the previous exemplary embodiments, and are thus omitted for simplicity herein.

After the device D₁-D₆, D₁′ and D₂′ are completely placed in the preconfigured grid structure consisting BSG units 610-640 merged in a first arrangement, the processor 120 would count how many times of complete placement, denoted by k times, are already performed, and determines whether k is smaller than a predetermined number (also called episode) denoted by N (e.g. 15000). If the number of times of the complete placement does not reach the predetermined number (N), the processor 120 may generate one another initial state representing a different random assignment of locations of the devices in the same preconfigured grid structure, return to the new initial state and perform the complete placement in a similar way, until the number of times of complete placement is accumulated to the predetermined number (N). After reaching the predetermined number (N), the processor 120 changes the to an un-used grid structure consisting BSG units 610-640 merged in a second arrangement different from the first arrangement, and the processor 120 performs the training process in a similar way, until all of selectable arrangements of grid structure are used in the training process. On the other hand, the processor 120 may record the maximum reward in time, for example, the processor 120 may compare every current reward and the maximum reward stored in a register and rewrite the register only if a current reward is larger than the reward stored in the register. The processor 120 also records the placement plan which earns the maximum reward. In such a way, after the training process is completely done, the optimum placement plan is determined.

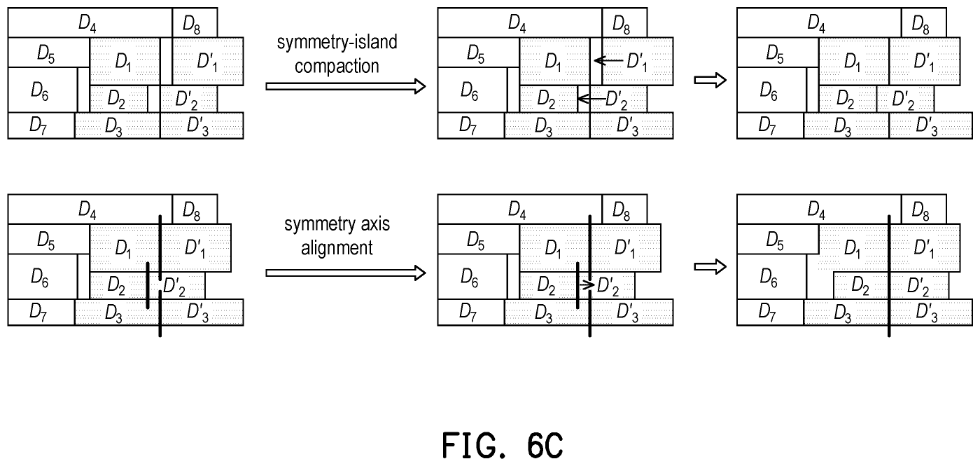

It should be noted that, due to the characteristics of the BSG structure, even though the placement on the BSG structure is symmetric, it may not be satisfied after compaction. Therefore, a symmetry-island refinement algorithm is proposed in schematic diagrams as illustrated in FIGS. 6A-6C in accordance with an exemplary embodiment of the disclosure. The symmetry-island refinement algorithm is utilized for adjusting the optimum placement plan determined by the training process. In one exemplary embodiment, the symmetry-island refinement algorithm comprising a symmetry-island compaction algorithm and a symmetry axis alignment algorithm.

In FIG. 6A, for each symmetry device group g, the processor 120 would find a symmetry axis for each symmetry pair (Dx, Dx′), where the direction may be either vertical or horizontal. In FIG. 6B, the processor 120 would divide each symmetry device group g into two categories gᵣ and g_{c}. Herein, gᵣ represents the device is in the same row, and g_{c} represents the device is in the same column.

Next, in a symmetry-island compaction step, for each gᵣ, the processor 120 would choose the middle device as a target device. In FIG. 6C, if a device is at the left side of the target device, then the processor 120 would move the device to the right and vice versa. In this step, the processor 120 would make sure there is no overlap between devices.

Next, in a symmetry axis alignment step, since all devices in the symmetry device group g is close to each other after compaction, the processor 120 would calculate the symmetry axis for each gᵣ, choose the maximum one as the common symmetry axis of g, and align the rest of the symmetry axes to the common symmetry axis.

It should also be noted that, in one exemplary embodiment, the processor 120 may receive a user designation on a constraint of a placement length and/or a constraint of a placement width of the analog circuit prior to the process in FIG. 2 or FIG. 3.

No element, act, or instruction used in the detailed description of disclosed embodiments of the present application should be construed as absolutely critical or essential to the present disclosure unless explicitly described as such. Also, as used herein, each of the indefinite articles “a” and “an” could include more than one item. If only one item is intended, the terms “a single” or similar languages would be used. Furthermore, the terms “any of” followed by a listing of a plurality of items and/or a plurality of categories of items, as used herein, are intended to include “any of”, “any combination of”, “any multiple of”, and/or “any combination of multiples of the items and/or the categories of items, individually or in conjunction with other items and/or other categories of items. Further, as used herein, the term “set” is intended to include any number of items, including zero. Further, as used herein, the term “number” is intended to include any number, including zero.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method for learning-based auto placement of analog circuit comprising:
acquiring a netlist file of an analog circuit comprising a plurality of devices, wherein the netlist file defines basic information describing each device of the plurality of devices and comprising connecting net names and size of the device;
obtaining a total number of a plurality of wells of the analog circuit and the number of devices sharing a first well which has the greatest number of devices sharing the same well among the plurality of wells, according to the netlist file;
determining the number of a plurality of bounded-sliceline grid (BSG) units according to the total number of the plurality of wells;
determining a size of each of the plurality of BSG units according to the number of devices sharing the first well; and
performing a training process by using a reinforcement learning model comprising an actor model and a critic model, to determine an optimum placement plan, wherein the training process comprising:
placing a first device block of the plurality of devices in a first grid structure consisting of the plurality of BSG units merged in a first arrangement, by using the reinforcement learning model, to form a first placement plan, wherein each device block of the plurality of devices is a device or a combination of at least two devices; and
placing the plurality of devices of the analog circuit in another grid structure consisting of the plurality of BSG units merged in an arrangement different from the first arrangement.

2. The method according to claim 1, wherein the number of the plurality of BSG units is not less than the total number of the plurality of wells.

3. The method according to claim 1 further comprising:
generating a plurality of node embedding information which are respectively corresponding to a plurality of device blocks of the analog circuit according to the netlist file, wherein each of the plurality of device blocks is a device or a combination of at least two devices of the analog circuit.

4. The method according to claim 3, wherein the plurality of node embedding information are generated by using an inductive representation learning model.

5. The method according to claim 1, wherein the step of placing the first device block of the plurality of devices in the first grid structure by using the reinforcement learning model comprises:
generating a plurality of actions as outputs of the actor model in response to a first node embedding information of a plurality of node embedding information which is as an input to the actor model, wherein the first node embedding information is corresponding to the first device block;
selecting a first action from the plurality of actions according to at least one placement constraint adapted for placing the first device block in the first grid structure, wherein the first action indicates a grid position of the first grid structure; and
generating a reward corresponding to the first placement plan formed in response to placing the first device block according to the first action.

6. The method according to claim 5, wherein the reward is a function of a placement area and a half-perimeter wirelength of the placement area of the analog circuit.

7. The method according to claim 5, wherein the step of placing the first device block of the plurality of devices in the first grid structure by using the reinforcement learning model comprises:
generating a first expected value as an output of the critic model, wherein the first expected value is with respect to a current state which represents a current placement plan before the first device block is being placed in the first grid structure according to the first action; and
generating a second expected value as another output of the critic model, wherein the second expected value is with respect to a new state next to the current state (sₜ) and the new state represents the first placement plan formed in response to that the first device block has been placed in the first grid structure according to the first action.

8. The method according to claim 7, wherein the step of placing the first device block of the plurality of devices in the first grid structure by using the reinforcement learning model further comprises:
computing a temporal difference error according to the reward, the first expected value, and the second expected value.

9. The method according to claim 8, wherein the step of placing the first device block of the plurality of devices in the first grid structure by using the reinforcement learning model further comprises:
updating parameters of the actor model according to the temporal difference error by leveraging Proximal Policy Optimization algorithm; and
updating parameters of the critic model according to the temporal difference error, the first expected value, and the second expected value.

10. The method according to claim 1, wherein the step of placing the first device block of the plurality of devices in the first grid structure by using the reinforcement learning model comprises:
inputting a first node embedding information to the actor model and the critic model according a placement priority which is determined according to the importance of a plurality of device blocks of the analog circuit, wherein each of the plurality of device blocks is a device or a combination of at least two devices of the analog circuit and the first node embedding information is corresponding to the first device block.

11. The method according to claim 10, wherein the placement priority among the device blocks of the analog circuit is that a differential pair is higher than an operational amplifier current mirror, higher than a bias current mirror, higher than a capacitor, higher than other devices, and wherein a device or a device block with the largest area among devices or device blocks having the same the placement priority are placed first.

12. The method according to claim 5, wherein the at least one placement constraint comprises a well-island constraint which allows allocating the same MOS type of devices to the same BSG unit.

13. The method according to claim 5, wherein the at least one of placement constraint comprises a proximity constraint which allows allocating devices in a proximity device group to be placed in proximity to each other.

14. The method according to claim 1, wherein the at least one placement constraint comprises a symmetry-island constraint which allows devices in a symmetry device group to be placed proximity and symmetrically to each other.

15. The method according to claim 1, further comprising:
adjusting the optimum placement plan based on a symmetry-island refinement algorithm comprising a symmetry-island compaction algorithm and a symmetry axis alignment algorithm.
